(19) United States
(12) Patent Application Publication
(10) Pub. No.: US 2024/0331985 A1
(43) Pub. Date: Oct. 3, 2024

(54) ELECTROSTATIC CHUCK

(71) Applicant: TOTO LTD., Fukuoka (JP)

(72) Inventors: Ryosuke SAKURAI, Fukuoka (JP); Keisuke SANO, Fukuoka (JP); Masafumi IKEGUCHI, Fukuoka (JP); Jun SHIRAISHI, Fukuoka (JP); Ikuo ITAKURA, Fukuoka (JP); Yutaka MOMIYAMA, Fukuoka (JP)

(73) Assignee: TOTO LTD., Fukuoka (JP)

(21) Appl. No.: 18/610,491

(22) Filed: Mar. 20, 2024

(30) Foreign Application Priority Data
Mar. 27, 2023 (JP) 2023-049639
Mar. 27, 2023 (JP) 2023-049640
Mar. 27, 2023 (JP) 2023-049641

(51) Int. Cl. H01J 37/32; C23C 16/458; H01L 21/683

(52) U.S. Cl. CPC H01J 37/32715; C23C 16/4583; H01J 2237/2007; H01J 2237/3321; H01L 21/6833

(57) ABSTRACT

An electrostatic chuck includes: a dielectric substrate in which a through hole is formed; an RF electrode which is embedded inside the dielectric substrate; and an attracting electrode which is embedded inside the dielectric substrate at a position that is closer to a placement surface than the RF electrode. When viewed from a direction perpendicular to the placement surface, a circular first opening which is concentric with the through hole and which includes the through hole is formed in the attracting electrode and a circular second opening which is concentric with the through hole and which includes the through hole is formed in the RF electrode. A radius of the second opening is larger than a radius of the first opening.

### CROSS-REFERENCE TO RELATED APPLICATION

This application is based upon and claims the benefit of priority from Japanese Patent Applications No. 2023-049639 filed on Mar. 27, 2023, No. 2023-049640 filed on Mar. 27, 2023, and No. 2023-049641 filed on Mar. 27, 2023, the entire contents of which are incorporated herein by reference.

### BACKGROUND OF THE INVENTION

### Field of the Invention

The present invention relates to an electrostatic chuck.

### Description of the Related Art

Semiconductor manufacturing equipment such as a CVD device is provided with an electrostatic chuck as a device for attracting and holding a substrate such as a silicon wafer to be a processing object. The electrostatic chuck includes a dielectric substrate provided with an attracting electrode. When voltage is applied to the attracting electrode, an electrostatic force is created and a substrate placed on the dielectric substrate is attracted and held.

As described in Japanese Patent Laid-Open No. 2011-119654 below, an RF electrode being one of a pair of counter electrodes for generating plasma in semiconductor manufacturing equipment may be built into a dielectric substrate. In this case, both an attracting electrode and the RF electrode are built into the dielectric substrate.

In addition, a through hole which perpendicularly penetrates a placement surface is often formed in a dielectric substrate. Such a through hole is formed for the purpose of supplying an inert gas such as helium between the dielectric substrate and a substrate and the like. A circular opening is formed in a portion that overlaps with the through hole in a top view in each of the attracting electrode and the RF electrode so as to prevent the attracting electrode and the like from being exposed on an inner surface of the through hole. The opening is formed so as to be concentric with the through hole and to include the through hole.

During processing of a substrate, while the attracting electrode attains a high potential, the RF electrode is kept at a predetermined low potential (for example, the same ground potential as a base plate which supports the dielectric substrate). At this point, in the through hole, for example, a strong electric field is created from an edge of the opening of the attracting electrode toward an edge of the opening of the RF electrode. Since a direction of such an electric field is the same as a direction in which the through hole extends, there is a possibility that a dielectric breakdown may occur in a path through the through hole.

The present invention has been made in consideration of the problem described above and an object thereof is to provide an electrostatic chuck which is capable of suppressing an occurrence of an electrical breakdown through a through hole.

### SUMMARY OF THE INVENTION

As an aspect for solving the problem described above, an electrostatic chuck according to the present invention includes: a dielectric substrate which includes a placement surface on which an attracted object is to be placed and in which a through hole is perpendicularly formed with respect to the placement surface; an RF electrode which is embedded inside the dielectric substrate; and an attracting electrode which is embedded inside the dielectric substrate at a position that is closer to the placement surface than the RF electrode. When viewed from a direction perpendicular to the placement surface, a circular first opening which is concentric with the through hole and which includes the through hole is formed in the attracting electrode and a circular second opening which is concentric with the through hole and which includes the through hole is formed in the RF electrode. In the electrostatic chuck, a radius of the second opening is larger than a radius of the first opening.

In the electrostatic chuck configured as described above, an edge of the second opening formed in the RF electrode is farther from the through hole than an edge of the first opening formed in the attracting electrode. In the through hole, since a component of the electric field directed from the edge of the first opening toward the edge of the second opening decreases in a direction in which the through hole extends, the possibility that a dielectric breakdown may occur through the through hole can be reduced as compared to conventional configurations.

In addition, in the electrostatic chuck according to the present invention, a difference between the radius of the second opening and the radius of the first opening is also preferably equal to or smaller than 2.7 mm. Since the larger the radius of the second opening, the farther the edge of the second opening from the through hole, the possibility of an occurrence of a dielectric breakdown through the through hole decreases. However, making the radius of the second opening excessively large may result in the electric field around the attracting electrode at high potential affecting another portion through the second opening and may cause an occurrence of a dielectric breakdown in the portion. Findings obtained and confirmed through experiments and the like conducted by the present inventors indicate that the occurrence of such a dielectric breakdown can be prevented by making the difference between the radius of the second opening and the radius of the first opening equal to or smaller than 2.7 mm.

Furthermore, in the electrostatic chuck according to the present invention, the through hole is also preferably a hole for supplying gas. When the through hole is a hole for supplying gas, pressure inside the through hole becomes a pressure region where a dielectric breakdown relatively readily occurs. In such a case, an effect of applying the present invention described above is particularly significant.

As another aspect for solving the problem described above, an electrostatic chuck according to the present invention includes: a dielectric substrate which includes a placement surface on which an attracted object is to be placed and in which a through hole is perpendicularly formed with respect to the placement surface; and an RF electrode which is embedded inside the dielectric substrate. A circular opening which is concentric with the through hole and which includes the through hole is formed in the RF electrode and a radius of the opening is equal to or larger than 1.75 mm.

In the electrostatic chuck configured as described above, since the radius of the opening formed in the RF electrode is equal to or larger than 1.75 mm, an edge of the opening is at a sufficiently distant position from an inner surface of the through hole. In the through hole, a component of an electric field directed from a high-potential portion toward the edge of the opening decreases in a direction in which the through hole extends. Accordingly, the possibility that a dielectric breakdown may occur through the through hole can be reduced as compared to conventional configurations. Note that the “high-potential portion” described above is, for example, an attracting electrode embedded in the dielectric substrate.

In addition, in the electrostatic chuck according to the present invention, a radius of the opening is also preferably equal to or smaller than 5.35 mm. Since the larger the radius of the opening, the farther the edge of the opening from the inner surface of the through hole, the possibility of an occurrence of a dielectric breakdown through the through hole decreases. However, making the radius of the opening excessively large may result in the electric field around a portion (for example, the attracting electrode) with higher potential on a side closer to the placement surface than the RF electrode affecting another portion through the opening and may cause an occurrence of a dielectric breakdown in the portion. Findings obtained and confirmed through experiments and the like conducted by the present inventors indicate that the occurrence of such a dielectric breakdown can be prevented by making the radius of the opening equal to or smaller than 5.35 mm.

Furthermore, in the electrostatic chuck according to the present invention, the through hole is also preferably a hole for supplying gas. When the through hole is a hole for supplying gas, pressure inside the through hole becomes a pressure region where a dielectric breakdown relatively readily occurs. In such a case, an effect of applying the present invention described above is particularly significant.

As yet another aspect for solving the problem described above, an electrostatic chuck according to the present invention includes: a dielectric substrate which includes a placement surface on which an attracted object is to be placed and in which a through hole is perpendicularly formed with respect to the placement surface; and an RF electrode which is embedded inside the dielectric substrate. A circular opening which is concentric with the through hole and which includes the through hole is formed in the RF electrode and a difference between a radius of the opening and a radius in a portion of the through hole closest to a side of the placement surface is equal to or larger than 1.6 mm.

In the electrostatic chuck configured as described above, an edge of the opening formed in the RF electrode is at a position separated by 1.6 mm or more from an inner surface of the through hole. In the through hole, a component of an electric field directed from a high-potential portion toward the edge of the opening decreases in a direction in which the through hole extends. Accordingly, the possibility that a dielectric breakdown may occur through the through hole can be reduced as compared to conventional configurations. Note that the “high-potential portion” described above is, for example, an attracting electrode embedded in the dielectric substrate.

In addition, in the electrostatic chuck according to the present invention, a difference between the radius of the opening and the radius in a portion of the through hole closest to the side of the placement surface is also preferably equal to or smaller than 5.4 mm. Since the larger the radius of the opening, the farther the edge of the opening from the inner surface of the through hole, the possibility of an occurrence of a dielectric breakdown through the through hole decreases. However, making the radius of the opening excessively large may result in the electric field around a portion (for example, the attracting electrode) with high potential on a side closer to the placement surface than the RF electrode affecting another portion through the opening and may cause an occurrence of a dielectric breakdown in the portion. Findings obtained and confirmed through experiments and the like conducted by the present inventors indicate that the occurrence of such a dielectric breakdown can be prevented by making the difference between the radius of the opening and the radius in a portion of the through hole closest to the side of the placement surface equal to or smaller than 5.4 mm.

Furthermore, in the electrostatic chuck according to the present invention, the through hole is also preferably a hole for supplying gas. When the through hole is a hole for supplying gas, pressure inside the through hole becomes a pressure region where a dielectric breakdown relatively readily occurs. In such a case, an effect of applying the present invention described above is particularly significant.

### Advantageous Effect of Invention

According to the present invention, an electrostatic chuck capable of suppressing an occurrence of a dielectric breakdown through a through hole can be provided.

### BRIEF DESCRIPTION OF THE DRAWINGS

FIG. 1 is a sectional view schematically showing a configuration of an electrostatic chuck according to a first embodiment;

FIG. 2 is a structure showing, enlarged and in detail, a part of a structure shown in FIG. 1;

FIG. 3A is a diagram for describing a relationship between a shape of an RF electrode and the like and susceptibility to a dielectric breakdown;

FIG. 3B is a diagram for describing a relationship between a shape of an RF electrode and the like and susceptibility to a dielectric breakdown;

FIG. 4A is a diagram for describing a relationship between a shape of an RF electrode and the like and susceptibility to a dielectric breakdown;

FIG. 4B is a diagram for describing a relationship between a shape of an RF electrode and the like and susceptibility to a dielectric breakdown;

FIG. 5 is a sectional view showing, enlarged and in detail, a part of a structure of an electrostatic chuck according to a second embodiment;

FIG. 6A is a diagram for describing a relationship between a shape of an RF electrode and the like and susceptibility to a dielectric breakdown;

FIG. 6B is a diagram for describing a relationship between a shape of an RF electrode and the like and susceptibility to a dielectric breakdown;

FIG. 7A is a diagram for describing a relationship between a shape of an RF electrode and the like and susceptibility to a dielectric breakdown; and

FIG. 7B is a diagram for describing a relationship between a shape of an RF electrode and the like and susceptibility to a dielectric breakdown.

### DETAILED DESCRIPTION OF THE PREFERRED EMBODIMENTS

Hereinafter, embodiments of the present invention will be described with reference to the accompanying drawings. In order to facilitate understanding of the description, the same constituent elements in the respective drawings will be denoted by the same reference signs whenever possible and redundant descriptions will not be repeated.

A first embodiment will be described. An electrostatic chuck 10 according to the present embodiment attracts a substrate W to be a processing object using an electrostatic force and holds the substrate W inside semiconductor manufacturing equipment (not illustrated) such as a CVD film deposition device. For example, the substrate W is a silicon wafer. The electrostatic chuck 10 may be used in devices other than semiconductor manufacturing equipment.

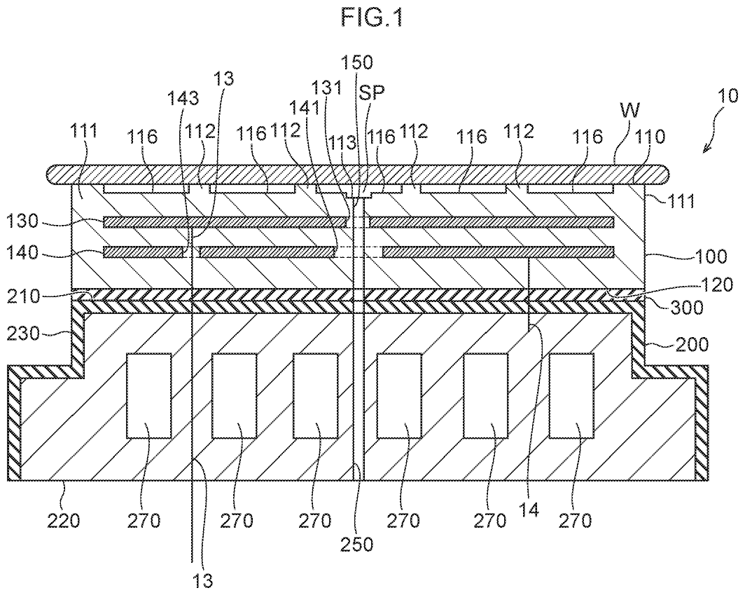

FIG. 1 shows a configuration of the electrostatic chuck 10 in a state where the substrate W has been attracted and is held as a schematic sectional view. The electrostatic chuck 10 includes a dielectric substrate 100, a base plate 200, and a joining layer 300.

The dielectric substrate 100 is an approximately disk-shaped member made of a ceramic sintered compact. While the dielectric substrate 100 includes, for example, high-grade aluminum oxide (Al₂O₃), the dielectric substrate 100 may include other materials. A purity, a type, an additive, and the like of ceramics in the dielectric substrate 100 can be appropriately set in consideration of plasma resistance and the like which are required of the dielectric substrate 100 in the semiconductor manufacturing equipment.

In FIG. 1, an upper-side surface 110 of the dielectric substrate 100 is a “placement surface” on which the substrate W that is an attracted object is placed. In addition, a lower-side surface 120 of the dielectric substrate 100 in FIG. 1 is a “joined surface” to be joined to the base plate 200 via the joining layer 300 to be described later. Hereinafter, a point of view when viewing the electrostatic chuck 10 from a side of the surface 110 in a direction perpendicular to the surface 110 will also be notated as a “top view”.

An attracting electrode 130 is embedded in the dielectric substrate 100. The attracting electrode 130 is a thin plate-like layer formed of a metal material such as tungsten and is arranged so as to be parallel to the surface 110. As the material of the attracting electrode 130, molybdenum, platinum, palladium, and the like may be used in addition to tungsten. When voltage is applied to the attracting electrode 130 from outside via a power feed path 13, an electrostatic force is created between the surface 110 and the substrate W and, accordingly, the substrate W is attracted and held. While only one attracting electrode 130 may be provided as in the present embodiment as a so-called “monopolar” electrode, alternatively, two attracting electrodes 130 may be provided as so-called “bipolar” electrodes.

In FIG. 1, an entirety of the power feed path 13 is drawn in a simplified manner. Within the power feed path 13, a portion inside the dielectric substrate 100 is configured as, for example, an elongated via (hole) filled with a conductive material and an electrode terminal (not illustrated) is provided at a lower end thereof. A portion of the power feed path 13 which penetrates the base plate 200 is a conductive metal member (for example, a busbar) of which one end is connected to the electrode terminal described above. A through hole (not illustrated) for inserting the power feed path 13 is formed in the base plate 200. For example, a cylindrical insulation member may be provided between an inner surface of the through hole and the power feed path 13.

In addition to the attracting electrode 130 described above, an RF electrode 140 is also embedded in the dielectric substrate 100. The RF electrode 140 is provided as one of a pair of counter electrodes for generating plasma in the semiconductor manufacturing equipment. Another of the pair of counter electrodes is provided at a position above the electrostatic chuck 10 in the semiconductor manufacturing equipment. When a high-frequency AC voltage is applied between the counter electrodes, plasma is generated above the substrate W to be used for processing such as film formation and etching with respect to the substrate W.

The RF electrode 140 is a thin plate-like layer formed of a metal material such as tungsten in a similar manner to the attracting electrode 130. As the material of the RF electrode 140, molybdenum, platinum, palladium, and the like may be used in addition to tungsten. The RF electrode 140 is embedded at a position closer to the side of the surface 120 than the attracting electrode 130. In other words, the attracting electrode 130 is embedded at a position closer to the side of the surface 110 than the RF electrode 140. The RF electrode 140 is arranged so as to be parallel to the surface 110 and the attracting electrode 130 in a similar manner to the attracting electrode 130. The RF electrode 140 is a single approximately circular electrode in a top view.

An opening 143 is formed in a portion of the RF electrode 140 overlapping with the power feed path 13 in a top view. By forming the opening 143, insulation between the power feed path 13 and the RF electrode 140 is secured.

As shown in FIG. 1, a power feed path 14 is connected to the RF electrode 140. The power feed path 14 is an electrical path for matching a potential of the RF electrode 140 with a potential of the base plate 200 when applying a high-frequency AC voltage between the RF electrode 140 and the other counter electrode. In FIG. 1, an entirety of the power feed path 14 is drawn in a simplified manner. For example, the power feed path 14 is constructed as an electrode terminal of which one end is connected to the RF electrode 140 and another end protrudes downward from the surface 120. The portion of the power feed path 14 projected as described above is embedded in a recessed part (not illustrated) formed on the surface 120 of the base plate 200 and is connected to a metal portion of the base plate 200.

A space SP is formed between the dielectric substrate 100 and the substrate W. When processing such as film deposition is performed in the semiconductor manufacturing equipment, helium gas for temperature regulation is supplied to the space SP from outside via a gas hole 150 to be described later or the like. By interposing the helium gas between the dielectric substrate 100 and the substrate W, thermal resistance between the dielectric substrate 100 and the substrate W is regulated and, accordingly, the substrate W is kept at an appropriate temperature. Note that the gas for temperature regulation which is supplied to the space SP may be a gas other than helium.

A seal ring 111 and a dot 112 are provided on the surface 110 being an attraction surface and the space SP is formed around the seal ring 111 and the dot 112.

The seal ring 111 is a wall that partitions the space SP at an outermost position. An upper end of the seal ring 111 constitutes a part of the surface 110 and abuts the substrate W. Note that a plurality of seal rings 111 may be provided so as to divide the space SP. Adopting such a configuration enables pressure of helium gas in each space SP to be individually regulated and enables a surface temperature distribution of the substrate W during processing to be made nearly uniform.

In FIG. 1 and the like, portions denoted by a reference sign “116” are a bottom surface of the space SP. Hereinafter, the portions will also be referred to as the “bottom surface 116”. The seal rings 111 are formed together with the dot 112 to be described next as a result of thinning parts of the surface 110 down to a position of the bottom surface 116.

The dot 112 is a circular projection that protrudes from the bottom surface 116. The dot 112 is provided in plurality and arranged so as to be approximately uniformly distributed over the attraction surface of the dielectric substrate 100. An upper end of each dot 112 constitutes a part of the surface 110 and abuts the substrate W. Providing the dot 112 described above in plurality suppresses deflection of the substrate W.

A groove 113 is formed on the bottom surface 116 of the space SP. The groove 113 is a groove formed to cause the bottom surface 116 to further retreat towards the side of the surface 120. The groove 113 is formed in order to quickly diffuse the helium gas supplied from the gas hole 150 into the space SP and to make a pressure distribution in the space SP approximately uniform in a short period of time.

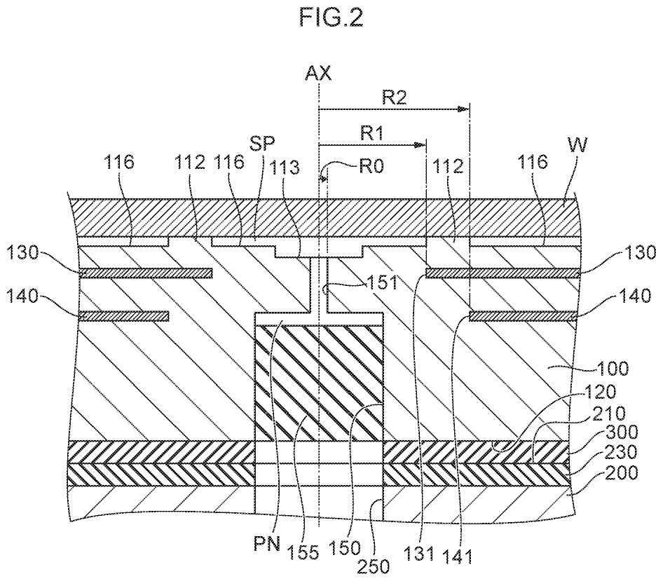

The gas hole 150 which perpendicularly extends from the surface 120 toward the side of the surface 110 is formed in the dielectric substrate 100 and the gas hole 150 is connected to the space SP via a through hole 151 shown in FIG. 2. While the gas hole 150 is formed in plurality, only one gas hole 150 is shown in FIG. 1.

The base plate 200 is an approximately disk-shaped member which supports the dielectric substrate 100. For example, the base plate 200 is formed of a metal such as aluminum. An upper-side surface 210 of the base plate 200 in FIG. 1 is a “joined surface” to be joined to the dielectric substrate 100 via the joining layer 300.

An insulator film 230 is formed on approximately the entire surface of the base plate 200 excluding a lower-side surface 220 in FIG. 1. The insulator film 230 is, for example, a film made of an insulating material such as alumina and is formed by, for example, spraying. An entirety of the surface 210 described earlier constitutes a surface on the insulator film 230. Note that a range where the insulator film 230 is formed within the base plate 200 may differ from a range according to the example shown in FIG. 1. For example, the insulator film 230 may only be formed in a range of the surface 210 which is a joined surface.

A refrigerant flow path 270 for supplying a refrigerant is formed inside the base plate 200. When processing such as film deposition is performed in the semiconductor manufacturing equipment, the refrigerant is supplied to the refrigerant flow path 270 from the outside and the base plate 200 is cooled by the refrigerant. Heat generated on the substrate W during the processing is transferred to the refrigerant via the helium gas in the space SP, the dielectric substrate 100, and the base plate 200 and discharged to the outside together with the refrigerant.

A gas hole 250 which perpendicularly extends from the surface 210 toward the side of the surface 220 is formed in the base plate 200. The gas hole 250 is formed at each position overlapping with the gas hole 150 of the dielectric substrate 100 in a top view and is communicated with the gas hole 150 via a through hole provided in the joining layer 300. Together with the gas hole 150 of the dielectric substrate 100, the gas hole 250 constitutes a part of a path for supplying helium gas towards the space SP.

While the gas hole 250 may be formed so that the entire gas hole 250 extends linearly as in the present embodiment, alternatively, the gas hole 250 may be formed so as to bend before reaching the surface 220. In addition, a configuration may be adopted in which after consolidating a plurality of the gas holes 250 on the side of the surface 210 into a small number of flow paths inside the base plate 200, the flow paths are extended to the side of the surface 220.

The joining layer 300 is a layer provided between the dielectric substrate 100 and the base plate 200 to join the dielectric substrate 100 and the base plate 200 to each other. The joining layer 300 is created by curing an adhesive made of an insulating material. As such an adhesive, for example, a silicone-based adhesive can be used.

A specific configuration of an upper end part and a portion in a vicinity thereof of the gas hole 150 will be described. FIG. 2 shows the configuration of the portion as a schematic sectional view. As shown in FIG. 2, while the gas hole 150 is formed so as to extend from the surface 120 toward the groove 113 at a position directly under the groove 113, the gas hole 150 does not reach the bottom surface of the groove 113. The gas hole 150 and the space SP are communicated with each other by the through hole 151.

The through hole 151 is a circular through hole which is formed so as to linearly extend from an upper end of the gas hole 150 to the bottom surface of the groove 113. A radius of the through hole 151 is smaller than a radius of the gas hole 150. In addition, a central axis AX of the through hole 151 matches a central axis of the gas hole 150. In other words, the through hole 151 extends in a direction perpendicular to the surface 110. Helium gas having passed through the gas hole 150 is supplied to the space SP from the through hole 151. The through hole 151 can also be described as a portion of the gas hole 150 closest to the side of the surface 110 or, in other words, an outlet portion of gas, the gas hole 150 being a through hole.

By reducing a radius of an outlet portion of gas of the gas hole 150 as described above, susceptibility to a dielectric breakdown through the gas hole 150 can be reduced. Instead of such an aspect, an aspect in which the gas hole 150 extends as-is to the bottom surface of the groove 113 may be adopted.

As shown in FIG. 2, a porous plug 155 is arranged inside the gas hole 150. The porous plug 155 is an approximately columnar member formed of a porous member with ventilation characteristics. A space PN is formed between an upper end of the porous plug 155 and an upper end of the gas hole 150. Arranging the porous plug 155 enables susceptibility to a dielectric breakdown between the substrate W and the base plate 200 to be further reduced. In a similar manner, a porous plug for preventing a dielectric breakdown may also be arranged in a portion of the gas hole 250 in a vicinity of the joining layer 300.

An opening 131 is formed in a portion of the attracting electrode 130 overlapping with the through hole 151 and the gas hole 150 in a top view. In a top view, the opening 131 is a circular opening and a center thereof is on the central axis AX. In addition, a radius R1 of the opening 131 is larger than a radius R0 of the through hole 151. In other words, the opening 131 is a circular opening which is concentric with the through hole 151 in a top view and which includes the through hole 151. Note that the radius R0 of the through hole 151 is, for example, equal to or smaller than 0.15 mm.

An opening 141 is formed in a portion of the RF electrode 140 overlapping with the through hole 151 and the gas hole 150 in a top view. In a top view, the opening 141 is a circular opening and a center thereof is on the central axis AX. In addition, a radius R2 of the opening 141 is larger than the radius R0 of the through hole 151. In other words, the opening 141 is a circular opening which is concentric with the through hole 151 in a top view and which includes the through hole 151.

The opening 131 corresponds to the “first opening” according to the present embodiment. The opening 141 corresponds to the “second opening” according to the present embodiment. By forming the opening 131 and the opening 141, the attracting electrode 130 and the RF electrode 140 are prevented from becoming exposed on the inner surface of the through hole 151.

In the present embodiment, the radius R2 of the opening 141 being the second opening is larger than the radius R1 of the opening 131 being the first opening.

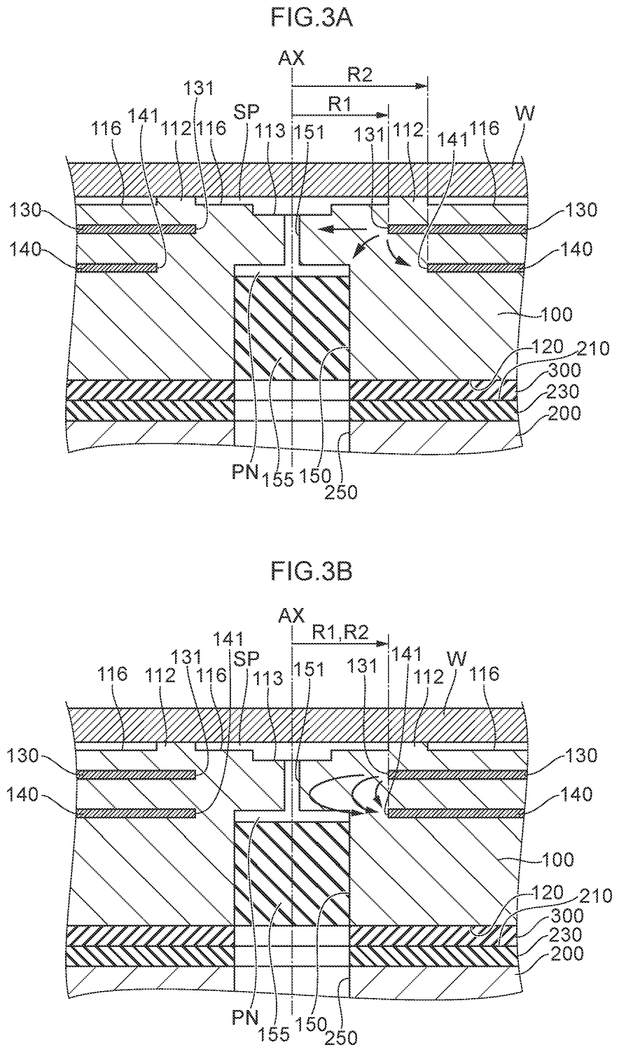

A reason for adopting such a configuration will now be described. FIG. 3B shows a configuration of a portion of an electrostatic chuck according to a comparative example, the portion corresponding to the portion shown in FIG. 2. In the comparative example, the radius R1 of the opening 131 and the radius R2 of the opening 141 are the same (more or less the same as the radius R1 shown in FIG. 3A and FIG. 3B).

During processing of the substrate W, while the attracting electrode 130 attains a high potential, the RF electrode 140 is kept at a predetermined low potential (the same potential as the base plate 200 which is, for example, a ground potential). Each arrow shown in FIG. 3B schematically represents a line of electric force in a vicinity of edges of the opening 141 and the opening 131. Each line of electric force extends from the edge of the opening 131 toward the edge of the opening 141. When the radius R1 of the opening 131 and the radius R2 of the opening 141 are the same as in the present comparative example, a direction of an electric field in the through hole 151 (in other words, a direction of the lines of electric force described above) is more or less the same as the direction in which the through hole 151 extends. Therefore, according to the configuration of the present comparative example, there is a possibility that a dielectric breakdown may occur in a path through the through hole 151.

In consideration thereof, in the electrostatic chuck 10 according to the present embodiment, a dielectric breakdown as described above is prevented by making the radius R2 of the opening 141 larger than the radius R1 of the opening 131.

FIG. 3A represents arrows indicating lines of electric force in a similar manner to FIG. 3B on the same cross section of the present embodiment as FIG. 2. In the present embodiment, due to having made the radius R2 of the opening 141 larger, only the edge of the opening 141 is distanced from the through hole 151. As a result, in the through hole 151, since a component of the electric field directed from the edge of the opening 131 toward the edge of the opening 141 decreases in a direction in which the through hole 151 extends, the possibility that a dielectric breakdown may occur through the through hole 151 can be reduced as compared to conventional configurations.

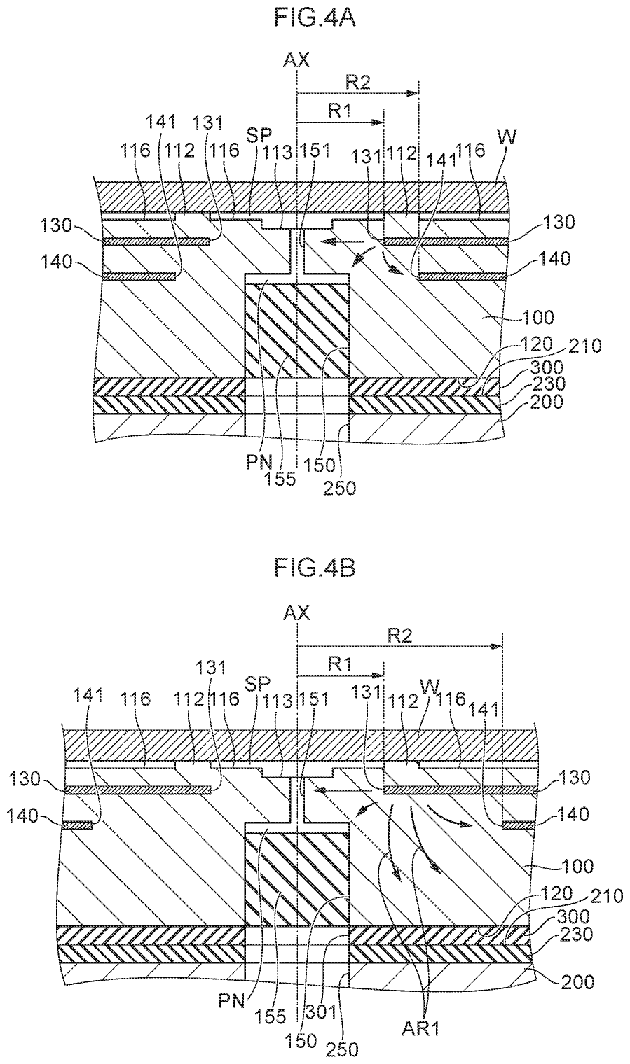

The larger the radius R2 of the opening 141, the lower the possibility of an occurrence of a dielectric breakdown in the through hole 151. FIG. 4B shows a comparative example in a case where the radius R2 has been excessively enlarged. FIG. 4A represents the same present embodiment as FIG. 3A.

When the radius R2 is excessively enlarged as in the comparative example shown in FIG. 4B, some of the lines of electric force extending from the attracting electrode 130 at a high potential may even affect a lower-side portion through the opening 141. For example, the lines of electric force indicated by arrows AR1 in FIG. 4B are not blocked by the RF electrode 140 and even create a potential difference in a portion in a vicinity of the joining layer 300. As a result, there is a possibility of an occurrence of a dielectric breakdown along the inner surface (a portion to which reference sign “301” is attached in FIG. 4B) of the through hole formed in the joining layer 300.

Findings obtained and confirmed through experiments and the like conducted by the present inventors indicate that the occurrence of such a dielectric breakdown can be sufficiently prevented by making the difference between the radius R2 of the opening 141 and the radius R1 of the opening 131 equal to or smaller than 2.7 mm. Therefore, without excessively enlarging the radius R2, the radius R2 is preferably set to radius R1+2.7 mm or less.

The difference between the radius R2 and the radius R0 is preferably within a range of 1.6 mm or more and 5.4 mm or less. In addition, the radius R2 is preferably within a range of 1.75 mm or more and 5.35 mm or less.

The opening 141 and the opening 131 described above may be formed at positions within the dielectric substrate 100 overlapping in a top view with a through hole provided for a purpose that differs from the through hole 151. For example, lift pin holes for inserting lift pins (not illustrated) provided in the semiconductor manufacturing equipment may be formed in the dielectric substrate 100. A similar effect to that described above can be produced by forming the opening 141 and the opening 131 similar to those according to the present embodiment at each position overlapping with the lift pin holes in a top view.

However, in the through hole 151 being a hole for supplying gas, pressure inside the through hole tends to become a pressure region where a dielectric breakdown relatively readily occurs. Therefore, at the position of the through hole 151, an effect of applying the shapes of the opening 141 and the opening 131 described above is particularly significant.

While a case where the radius R2 of the opening 141 (second opening) is made larger than the radius R1 of the opening 131 (first opening) has been described above, there may be cases where such a magnitude relationship is not essential. For example, when the radius R2 of the opening 141 is sufficiently large and, specifically, equal to or larger than 1.75 mm, the occurrence of a dielectric breakdown can be sufficiently suppressed regardless of the magnitude relationship between the radius R1 and the radius R2.

A reason therefor will be described. In the comparative example shown in FIG. 3B described earlier, the radius R2 of the opening 141 has been reduced to a similar extent as the radius R1 of the opening 131 and each line of electric force extends from the edge of the opening 131 toward the edge of the opening 141. Note that depending on a size of the opening 131, lines of electric force directed toward the edge of the opening 141 may extend from the substrate W being processed.

When the radius R2 of the opening 141 has been made relatively small as in the present comparative example, a direction of an electric field in the through hole 151 (in other words, a direction of the lines of electric force described above) is more or less the same as the direction in which the through hole 151 extends. Therefore, according to the configuration of the present comparative example, there is a possibility that a dielectric breakdown may occur in a path through the through hole 151.

In consideration thereof, there may be cases where a dielectric breakdown can be prevented by simply sufficiently enlarging the radius R2 in a similar manner to the present embodiment.

When the radius R2 of the opening 141 is sufficiently enlarged as in the present embodiment shown in FIG. 3A, the edge of the opening 141 is distanced from the through hole 151. As a result, in the through hole 151, a component of an electric field directed from a high-potential portion toward the edge of the opening 141 decreases in a direction in which the through hole 151 extends. While the “high-potential portion” is, for example, the attracting electrode 130, the “high-potential portion” may refer to the substrate W being processed in other cases.

Since a component of the electric field directed toward the opening 141 decreases in a direction in which the through hole 151 extends when the radius R2 is sufficiently increased as shown in FIG. 3A, the possibility that a dielectric breakdown may occur through the through hole 151 can be reduced as compared to conventional configurations.

Findings obtained and confirmed through experiments and the like conducted by the present inventors indicate that the occurrence of a dielectric breakdown through the through hole 151 can be sufficiently prevented by making the radius R2 equal to or larger than 1.75 mm.

Note that the effect described above of making the radius R2 equal to or larger than 1.75 mm is confirmed to be produced to a certain degree even when the radius R2 and the radius R1 are the same. In other words, even when not only the radius R2 but the radius R1 is also enlarged, an occurrence of a dielectric breakdown through the through hole 151 can be prevented. However, excessively enlarging the opening 131 of the attracting electrode 130 may result in an insufficient attracting force and creates a risk that the substrate W may not be sufficiently held. Therefore, only the opening 141 of the RF electrode 140 is preferably enlarged as in the present embodiment.

The larger the radius R2 of the opening 141, the lower the possibility of an occurrence of a dielectric breakdown in the through hole 151. When the radius R2 is excessively enlarged as in the comparative example shown in FIG. 4B, some of the lines of electric force extending from the portion at a high potential (in this example, the attracting electrode 130) may even affect a lower-side portion through the opening 141. For example, the lines of electric force indicated by arrows AR1 in FIG. 4B are not blocked by the RF electrode 140 and even create a potential difference in a portion in a vicinity of the joining layer 300. As a result, there is a possibility of an occurrence of a dielectric breakdown along the inner surface (a portion to which reference sign “301” is attached in FIG. 4B) of the through hole formed in the joining layer 300.

Findings obtained and confirmed through experiments and the like conducted by the present inventors indicate that the occurrence of such a dielectric breakdown can be prevented by making the radius R2 equal to or smaller than 5.35 mm. Therefore, without excessively enlarging the radius R2, the radius R2 is preferably set to 5.35 mm or less.

The difference between the radius R2 and the radius R0 is preferably within a range of 1.6 mm or more and 5.4 mm or less. In addition, when making the radius R2 larger than the radius R1 as in the present embodiment, the difference between the radius R2 and the radius R1 is preferably set to 2.7 mm or smaller.

The opening 141 and the opening 131 described above may be formed at positions within the dielectric substrate 100 overlapping in a top view with a through hole provided for a purpose that differs from the through hole 151. For example, lift pin holes for inserting lift pins (not illustrated) provided in the semiconductor manufacturing equipment may be formed in the dielectric substrate 100. A similar effect to that described above can be produced by forming the opening 141 and the opening 131 similar to those according to the present embodiment at each position overlapping with the lift pin holes in a top view.

However, in the through hole 151 being a hole for supplying gas, pressure inside the through hole tends to become a pressure region where a dielectric breakdown relatively readily occurs. Therefore, at the position of the through hole 151, an effect of applying the shapes of the opening 141 and the opening 131 described above is particularly significant.

A second embodiment will be described. Hereinafter, differences from the first embodiment will be mainly described and descriptions of features in common with the first embodiment will be omitted when appropriate.

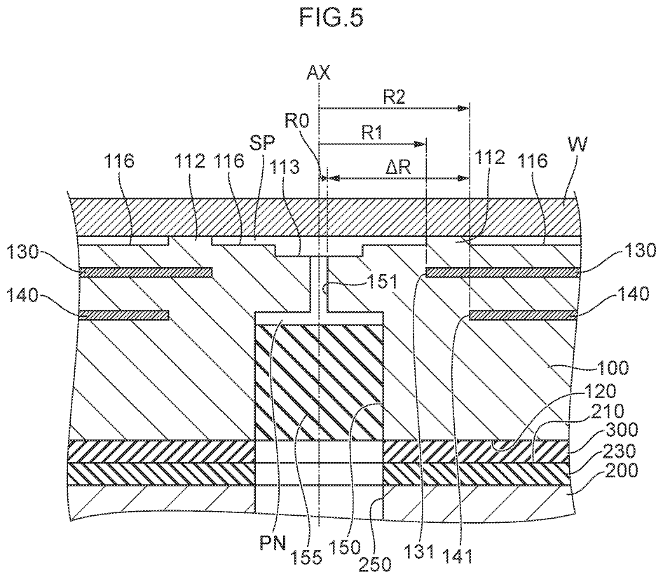

FIG. 5 shows a configuration of an upper end part of the gas hole 150 and a portion in a vicinity thereof within the electrostatic chuck 10 according to the present embodiment as a schematic sectional view.

In the present embodiment, the radius R2 of the opening 141 is sufficiently larger than the radius R0 of the through hole 151 and a difference (ΔR) between the radius R2 and the radius R0 equal to or larger than 1.6 mm is secured.

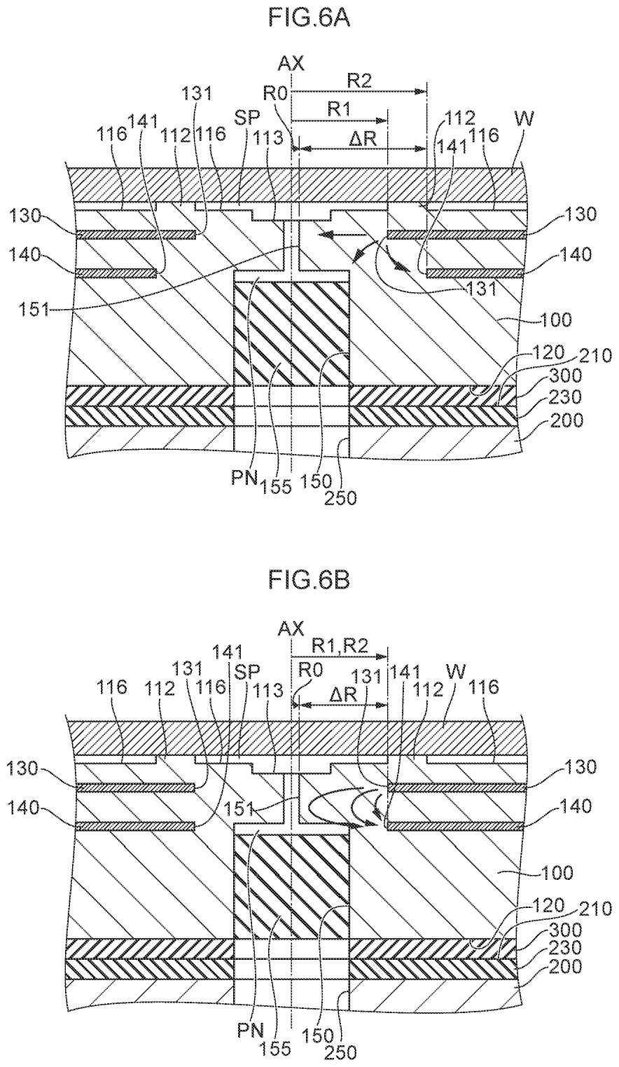

A reason for adopting such a configuration will now be described. FIG. 6B shows a configuration of a portion of an electrostatic chuck according to a comparative example, the portion corresponding to the portion shown in FIG. 5. In the comparative example, the radius R1 of the opening 131 and the radius R2 of the opening 141 are the same (more or less the same as the radius R1 shown in FIG. 5). As a result, ΔR described above is smaller than 1.6 mm and is around 1.0 mm.

During processing of the substrate W, while the attracting electrode 130 attains a high potential, the RF electrode 140 is kept at a predetermined low potential (the same potential as the base plate 200 which is, for example, a ground potential). Each arrow shown in FIG. 6B schematically represents a line of electric force in a vicinity of edges of the opening 141 and the opening 131. In FIG. 6B, each line of electric force extends from the edge of the opening 131 toward the edge of the opening 141. Note that depending on a size of the opening 131, lines of electric force directed toward the edge of the opening 141 may extend from the substrate W being processed.

When the edge of the opening 141 is close to the through hole 151 and ΔR is smaller than 1.6 mm as in the present comparative example, a direction of an electric field in the through hole 151 (in other words, a direction of the lines of electric force described above) is more or less the same as the direction in which the through hole 151 extends. Therefore, according to the configuration of the present comparative example, there is a possibility that a dielectric breakdown may occur in a path through the through hole 151.

In consideration thereof, in the electrostatic chuck 10 according to the present embodiment, a dielectric breakdown as described above is prevented by making the radius R2 of the opening 141 large so that ΔR equal to or larger than 1.6 mm is secured.

FIG. 6A represents arrows indicating lines of electric force in a similar manner to FIG. 6B on the same cross section of the present embodiment as FIG. 5. In the present embodiment, due to having made the radius R2 of the opening 141 larger, the edge of the opening 141 is distanced from the through hole 151. As a result, in the through hole 151, a component of an electric field directed from a high-potential portion toward the edge of the opening 141 decreases in a direction in which the through hole 151 extends. While the “high-potential portion” is, for example, the attracting electrode 130, in other cases, the “high-potential portion” may refer to the substrate W being processed.

Since a component of the electric field directed toward the opening 141 decreases in a direction in which the through hole 151 extends in the present embodiment shown in FIG. 6A, the possibility that a dielectric breakdown may occur through the through hole 151 can be reduced as compared to conventional configurations.

Findings obtained and confirmed through experiments and the like conducted by the present inventors indicate that the occurrence of a dielectric breakdown through the through hole 151 can be sufficiently prevented by securing ΔR that is equal to or larger than 1.6 mm.

Note that the effect described above of making ΔR equal to or larger than 1.6 mm is confirmed to be produced to a certain degree even when the radius R2 and the radius R1 are the same. In other words, even when not only the radius R2 but the radius R1 is also enlarged, an occurrence of a dielectric breakdown through the through hole 151 can be prevented. However, excessively enlarging the opening 131 of the attracting electrode 130 may result in insufficient attracting force and creates a risk that the substrate W may not be sufficiently held. Therefore, only the opening 141 of the RF electrode 140 is preferably enlarged as in the present embodiment.

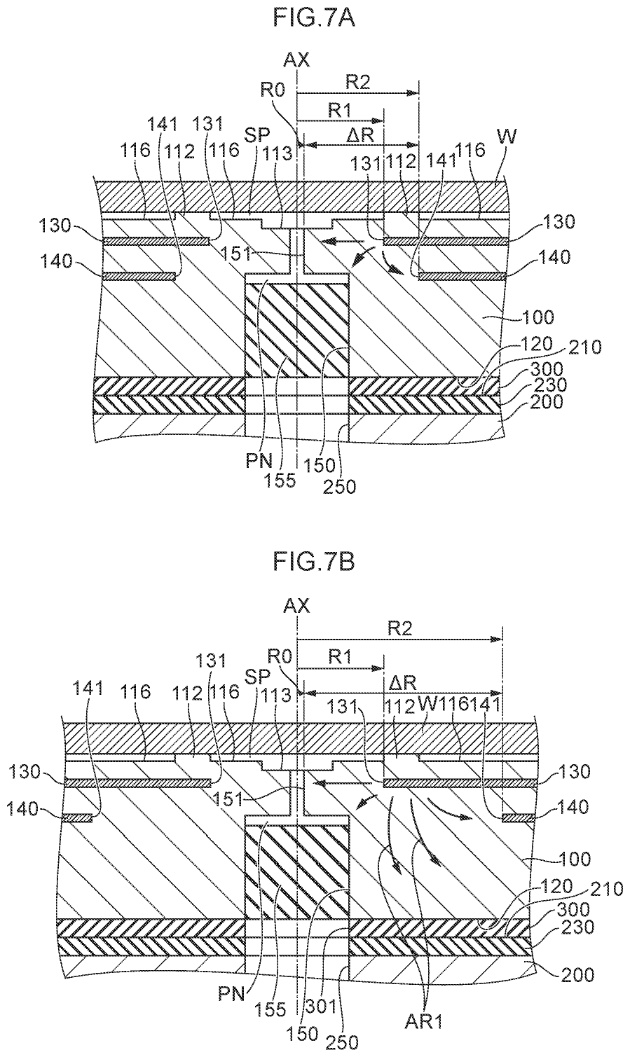

The larger the radius R2 of the opening 141 or, in other words, the larger the value of ΔR, the lower the possibility of an occurrence of a dielectric breakdown in the through hole 151. FIG. 7B shows a comparative example in a case where the radius R2 has been excessively enlarged. FIG. 7A represents the same present embodiment as FIG. 6A.

When the radius R2 or ΔR is excessively enlarged as in the comparative example shown in FIG. 7B, some of the lines of electric force extending from the portion at a high potential (in this example, the attracting electrode 130) may even affect a lower-side portion through the opening 141. For example, the lines of electric force indicated by arrows AR1 in FIG. 7B are not blocked by the RF electrode 140 and even create a potential difference in a portion in a vicinity of the joining layer 300. As a result, there is a possibility of an occurrence of a dielectric breakdown along the inner surface (a portion to which reference sign “301” is attached in FIG. 7B) of the through hole formed in the joining layer 300.

Findings obtained and confirmed through experiments and the like conducted by the present inventors indicate that the occurrence of such a dielectric breakdown can be prevented by making ΔR equal to or smaller than 5.4 mm. Therefore, without excessively enlarging the radius R2, the radius R2 is preferably set to radius R0+5.4 mm or less.

The radius R2 is preferably within a range of 1.75 mm or more and 5.35 mm or less. In addition, when making the radius R2 larger than the radius R1 as in the present embodiment, the difference between the radius R2 and the radius R1 is preferably set to 2.7 mm or smaller.

The opening 141 and the opening 131 described above may be formed at positions within the dielectric substrate 100 overlapping in a top view with a through hole provided for a purpose that differs from the through hole 151. For example, lift pin holes for inserting lift pins (not illustrated) provided in the semiconductor manufacturing equipment may be formed in the dielectric substrate 100. A similar effect to that described above can be provided by forming the opening 141 and the opening 131 similar to those according to the present embodiment at each position overlapping with the lift pin holes in a top view.

However, in the through hole 151 being a hole for supplying gas, pressure inside the through hole tends to become a pressure region where a dielectric breakdown relatively readily occurs. Therefore, at the position of the through hole 151, an effect of applying the shapes of the opening 141 and the opening 131 described above is particularly significant.

The present embodiment has been described above with reference to specific examples. However, it is to be understood that the present disclosure is not limited to the specific examples. Appropriate design modifications of the specific examples made by persons skilled in the art are also included in the scope of the present disclosure insofar as such modifications possess features of the present disclosure. The respective elements included in each specific example described above and arrangements, conditions, shapes, and the like of such elements are not limited to those exemplified and can be modified as appropriate. Combinations of the respective elements included in each specific example described above can be appropriately changed insofar as no technical contradictions arise from such changes.

What is claimed is:

1. An electrostatic chuck, comprising:
a dielectric substrate which includes a placement surface on which an attracted object is to be placed and in which a through hole is perpendicularly formed with respect to the placement surface;
an RF electrode which is embedded inside the dielectric substrate; and
an attracting electrode which is embedded inside the dielectric substrate at a position that is closer to the placement surface than the RF electrode, wherein
when viewed from a direction perpendicular to the placement surface,
a circular first opening which is concentric with the through hole and which includes the through hole is formed in the attracting electrode,
a circular second opening which is concentric with the through hole and which includes the through hole is formed in the RF electrode, and
a radius of the second opening is larger than a radius of the first opening.

2. The electrostatic chuck according to claim 1, wherein a difference between the radius of the second opening and the radius of the first opening is equal to or smaller than 2.7 mm.

3. The electrostatic chuck according to claim 1, wherein the through hole is a hole for supplying gas.

4. The electrostatic chuck according to claim 2, wherein the through hole is a hole for supplying gas.

5. An electrostatic chuck, comprising:
a dielectric substrate which includes a placement surface on which an attracted object is to be placed and in which a through hole is perpendicularly formed with respect to the placement surface; and
an RF electrode which is embedded inside the dielectric substrate, wherein
a circular opening which is concentric with the through hole and which includes the through hole is formed in the RF electrode, and
a radius of the opening is equal to or larger than 1.75 mm.

6. The electrostatic chuck according to claim 5, wherein the radius of the opening is equal to or smaller than 5.35 mm.

7. The electrostatic chuck according to claim 5, wherein the through hole is a hole for supplying gas.

8. The electrostatic chuck according to claim 6, wherein the through hole is a hole for supplying gas.

9. An electrostatic chuck, comprising:
a dielectric substrate which includes a placement surface on which an attracted object is to be placed and in which a through hole is perpendicularly formed with respect to the placement surface; and
an RF electrode which is embedded inside the dielectric substrate, wherein
a circular opening which is concentric with the through hole and which includes the through hole is formed in the RF electrode, and
a difference between a radius of the opening and a radius in a portion of the through hole closest to a side of the placement surface is equal to or larger than 1.6 mm.

10. The electrostatic chuck according to claim 9, wherein a difference between the radius of the opening and the radius in a portion of the through hole closest to a side of the placement surface is equal to or smaller than 5.4 mm.

11. The electrostatic chuck according to claim 9, wherein the through hole is a hole for supplying gas.

12. The electrostatic chuck according to claim 10, wherein the through hole is a hole for supplying gas.
